(19) United States
(12) Patent Application Publication
(10) Pub. No.: US 2026/0305222 A1
(43) Pub. Date: Oct. 1, 2026

(54) SPRAYING MEMBER AND METHOD OF PROCESSING SUBSTRATE USING THE SPRAYING MEMBER

(71) Applicant: TAIWAN SEMICONDUCTOR MANUFACTURING COMPANY LTD., HSINCHU (TW)

(72) Inventors: YOU-JHANG WU, TAINAN CITY (TW); MING-CHE LI, HSINCHU (TW); CHENG-KUANG CHEN, TAINAN CITY (TW); CHIH-WEI WEN, TAINAN CITY (TW)

(21) Appl. No.: 19/091,878

(22) Filed: Mar. 27, 2025

(51) Int. Cl. H01L 21/67

(52) U.S. Cl. CPC H10P 72/0404

(57) ABSTRACT

The present disclosure provides a method of processing a substrate. The method includes: placing a spraying member proximal to the substrate, wherein the spraying member includes a first segment and a second segment coupled to the first segment, the first segment is adjustable relative to the second segment, and the first segment has a first opening configured to discharge a fluid out of the spraying member; adjusting the first segment relative to the second segment; and discharging the fluid from the first opening. The adjustment of the first segment includes extending the first segment from the second segment, retracting the first segment toward the second segment, or rotating the first segment relative to the second segment. The first opening is movable relative to and along a slot of the first segment. A size of the first opening is also adjustable.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the size of the smallest component (or line) that can be created using a fabrication process) has decreased. This scaling down process generally provides benefits by increasing production efficiency and lowering associated costs. Such scaling down has also increased the complexity of processing and manufacturing ICs.

For manufacturing a substrate, a spraying member such as a nozzle is often used to dispense a liquid onto a semiconductor substrate. As the complexity of IC processing increases, there is a need to improve the spraying member for delivering processing chemicals.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. Specifically, dimensions of the various features may be arbitrarily increased or reduced for clarity of discussion.

FIG. 1 is a schematic view of a semiconductor process apparatus or a process chamber of the semiconductor process apparatus, in accordance with some embodiments of the present disclosure.

FIGS. 2, 3A, 3B, 4 and 5 are enlarged views of different configurations of a spraying member of the semiconductor process apparatus, in accordance with different embodiments of the present disclosure.

FIGS. 6A to 6C are schematic views of slots and their corresponding openings, in accordance with different embodiments of the present disclosure.

FIGS. 7A to 7E are schematic views of various spraying members, in accordance with different embodiments of the present disclosure.

FIGS. 8A to 8C are schematic perspective views of various spraying members, in accordance with different embodiments of the present disclosure.

FIG. 9 is a flowchart of a method for processing a substrate, in accordance with some embodiments of the present disclosure.

FIGS. 10 to 13, 14A to 14C and 15 to 20 are schematic views showing some operations of the method in FIG. 9, in accordance with different embodiments of the present disclosure.

FIG. 21 is a flowchart of another method for processing a substrate, in accordance with some embodiments of the present disclosure.

FIGS. 22 to 25 are schematic views showing some operations of the method in FIG. 21, in accordance with different embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fluids are widely used in industry. These fluids include various gases and liquids such as chemicals and water which are used in a great amount in semiconductor processes. For example, when manufacturing an integrated circuit (IC), a lithographic process is used for reproducing layers to form structures on a semiconductor substrate. In a first step in the lithographic process, reagents such as hexamethyldisilazane (HMDS) are used to improve surface adhesion of a wafer. In a second step in the lithographic process, a photoresist layer is coated onto the substrate such that an image can be projected and developed thereon. The photoresist is a liquid that is coated as a thin layer on top of the substrate. In various processes for applying a surface treatment or applying a photoresist coating material to a substrate, a spin coater is normally used. The spin coater includes using a spraying member such as a nozzle to spray the coating material from an opening of the nozzle toward the substrate, and the substrate is rotated such that a uniform coating remains on the substrate. One or more materials may be so dispensed and coat the substrate.

A frontside, a backside or an edge of the substrate needs to be rinsed. Suitable chemicals may need to react with the coating material. The chemicals are dispensed to the substrate using the spraying member. As technology advancement, there is a need to improve the spraying member. For example, the spraying member needs to spray a chemical evenly on the substrate, or needs to be capable of spraying a chemical at different angles toward the substrate. In another example, a spraying member under different configurations may be required for different substrates having different dimensions.

The present disclosure is related to a spraying member and a method for using the spraying member to discharge fluids onto a surface of a substrate.

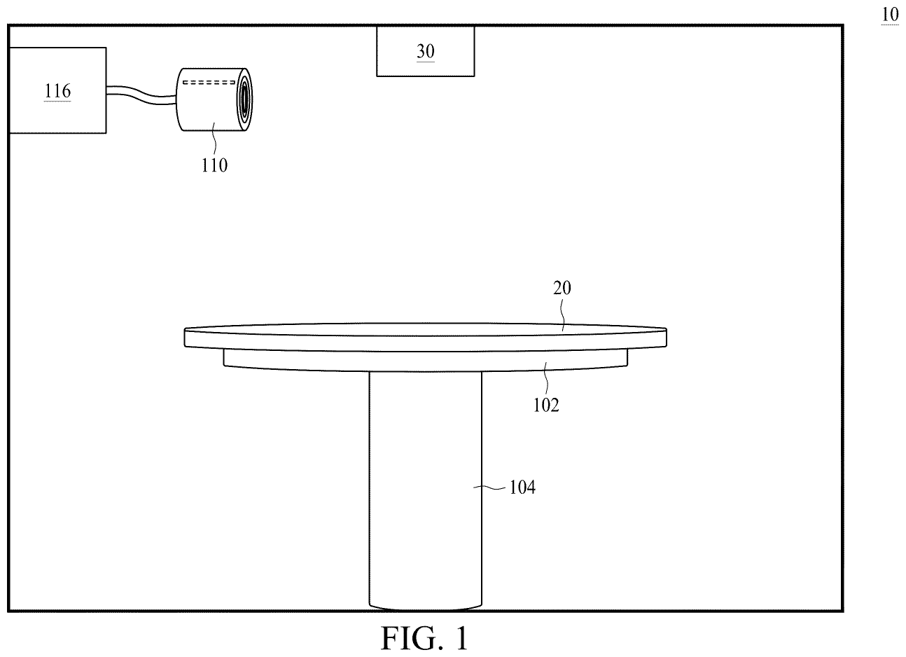

FIG. 1 is a schematic view of a semiconductor process apparatus 10 or a process chamber of the semiconductor process apparatus 10, according to some embodiments of the present disclosure. The semiconductor process apparatus 10 can be used to perform a manufacturing process such as spin coating, developing or cleaning. In some embodiments, the semiconductor process apparatus 10 includes a platform 102 for holding a substrate 20 and a spraying member 110 for dispensing one or more fluids toward the substrate 20. The substrate 20 may be placed on the platform 102 horizontally. In some embodiments, the substrate 20 includes at least one of a photomask, a reticle, a wafer, a wafer coated by a photoresist, a silicon substrate, a glass substrate and a ceramic substrate. In some embodiments, the substrate 20 has a diameter greater than a diameter of the platform 102.

In some embodiments, the platform 102 is circular-shaped and rotatable. A rotating motion of the platform 102 is achieved by a shaft 104 connected to and disposed below the platform 102. The shaft 104 can be powered by a motor to rotate at different speeds. In some embodiments, the platform 102 is a vacuum chuck configured to hold the substrate 20 securely during a manufacturing process.

In some embodiments, the spraying member 110 is a nozzle or an injector. In some embodiments, the spraying member 110 is disposed above or at a side of the platform 102, but the present disclosure is not limited thereto. In other embodiments, the spraying member 110 is disposed under the platform 102. The spraying member 110 can be moved to a central region or a peripheral region above the platform 102. The spraying member 110 is coupled to a liquid source (or a fluid source) 116 that supplies a liquid (or a fluid) to the spraying member 110. Positions of the spraying member 110 and the liquid source 116 shown in FIG. 1 are only schematic.

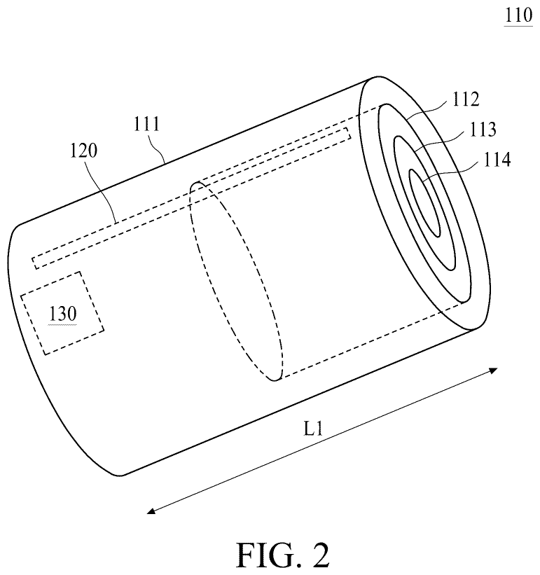

FIGS. 2, 3A, 3B, 4 and 5 are enlarged views of different configurations of the spraying member 110 in the semiconductor process apparatus 10, according to different embodiments of the present disclosure. Referring to FIG. 2, the spraying member 110 includes multiple segments, for example, segments 111, 112, 113 and 114 connected section by section. A number of the segments is not limited. In some embodiments, the segments 111, 112, 113 and 114 have different diameters. For example, the segment 111 has a greatest diameter, the segment 112 has a second greatest diameter, the segment 113 has a third greatest diameter, and the segment 114 has a least diameter. In some embodiments, a length L1 of the segment 111 is greater than a length of each of the segments 112, 113 and 114. The spraying member 110 includes multiple rails 120 respectively coupling adjacent segments. In some embodiments, a segment having a smaller diameter can be slid along the rail 120 and fit into its adjacent segment having a greater diameter. The segments 112, 113 and 114 can be stored in the segment 111, as shown in FIG. 2. In some embodiments, the spraying member 110 can be adjusted to be longer or shorter by adjusting an exposure of one or more of the segments 112, 113, and 114. That is, the spraying member 110 is a telescopic sprayer. In some embodiments, the spraying member 110 includes a motor 130 disposed internal or external to the spraying member. In some embodiments, the motor 130 is installed internal or external to the one or more of the segments 111, 112, 113 and 114.

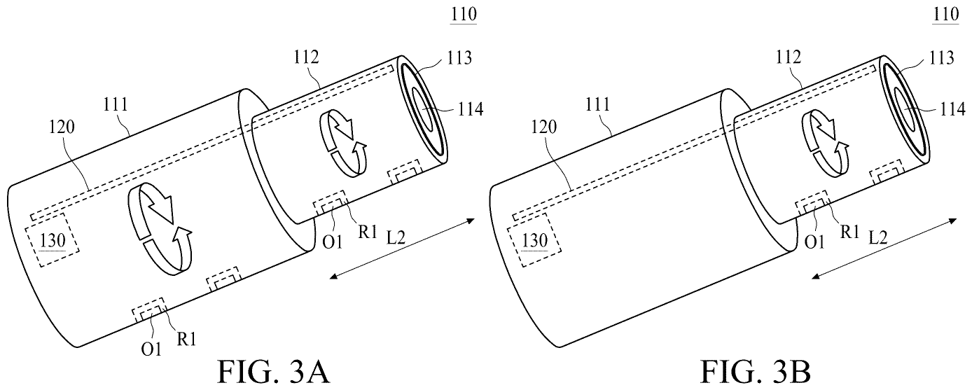

Referring to FIGS. 3A and 3B, FIGS. 3A and 3B respectively show the segment 112 extended from the segment 111, and the segments 113 and 114 stored in the segment 112. In some embodiments, each of the segments 111, 112, 113 and 114 includes one or more slots R1, as shown in FIG. 3A. The slots R1 of the segments 113 and 114 are not exposed in FIGS. 3A and 3B. In other embodiments, the segment 111 does not include any slot R1, as shown in FIG. 3B. That is, the segment 111 may or may not include the slot R1. In some embodiments, an opening O1 or an orifice O1 is disposed in the slot R1. The opening O1 is configured to allow a fluid to escape from the spraying member 110. In some embodiments, the segment 112 is adjustable relative to the segment 111 along the rail 120 disposed on the segment 111, on the segment 112 or across the segments 111 and 112. An exposed length L2 of the segment 112 can be adjusted by extending the segment 112 from the segment 111 or retracting the segment 112 toward the segment 111 while keeping the segment 111 stationary. In some embodiments, the segment 112 is rotatable relative to the segment 111. That is, when the segment 111 is stationary, the segment 112 can be rotated in a clockwise or counterclockwise direction, as shown by the arrow in FIGS. 3A and 3B. FIG. 3A shows the segment 111 and the segment 112 can be simultaneously rotated. FIG. 3B shows the segment 112 can be rotated while keeping the segment 111 stationary.

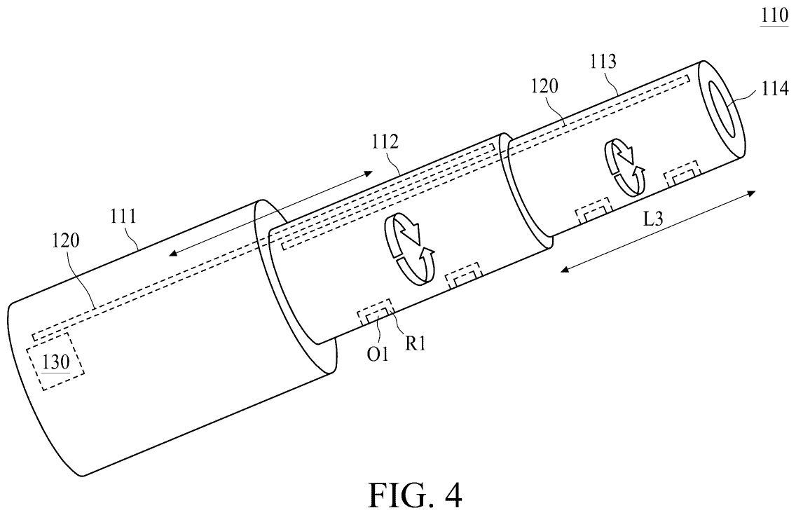

Referring to FIG. 4, FIG. 4 shows the segment 113 extended from the segment 112, and the segment 114 is stored in the segment 113. In some embodiments, the segment 113 is adjustable relative to the segment 112 along the rail 120 disposed on the segment 112, on the segment 113 or across the segments 112 and 113. An exposed length L3 of the segment 113 can be adjusted by extending the segment 113 from the segment 112 or retracting the segment 113 toward the segment 112 while keeping the segment 112 stationary. In some embodiments, the segment 113 is rotatable relative to the segment 112. That is, when the segment 112 is stationary, the segment 113 can be rotated, as shown by the arrow in FIG. 4. The segment 112 and the segment 113 can also be rotated simultaneously along a same direction or along different directions.

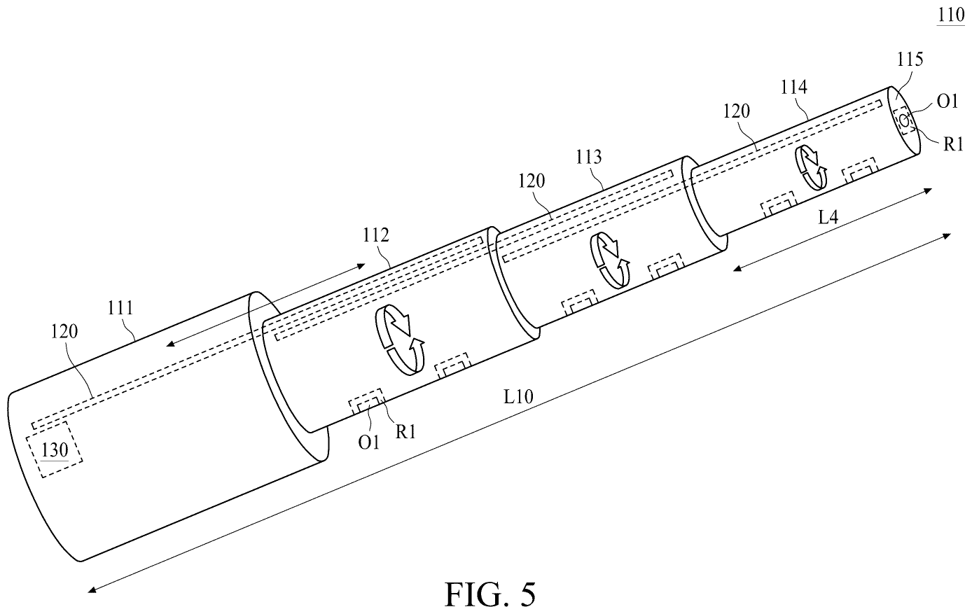

Referring to FIG. 5, FIG. 5 shows the segment 114 extended from the segment 113. In some embodiments, the segment 114 is adjustable relative to the segment 113 along the rail 120 disposed on the segment 113, on the segment 114 or across the segments 113 and 114. An exposed length L4 of the segment 114 can be adjusted by extending the segment 114 from the segment 113 or retracting the segment 114 toward the segment 113 while keeping the segment 113 stationary. In some embodiments, the segment 114 is rotatable relative to the segment 113. That is, when the segment 113 is stationary, the segment 114 can be rotated, as shown by the arrow in FIG. 5. The segment 113 and the segment 114 can also be rotated simultaneously along a same direction or along different directions. In some embodiments, a length L10 of the spraying member 110 is adjustable by tuning any of the exposed lengths L2, L3 and L4 of the segments 112, 113 and 114, respectively. The motor 130 can receive signals for controlling extension or contraction of the spraying member 110, or rotation of the segments 112, 113 and 114. In some embodiments, an opening O1 is disposed at an end 115 of the segment 114. In some embodiments, an opening O1 within a slot R1 is disposed at the end 115 of the segment 114. The opening O1 at the end 115 of the segment 114 can be also used to allow a fluid to flow from the spraying member 110.

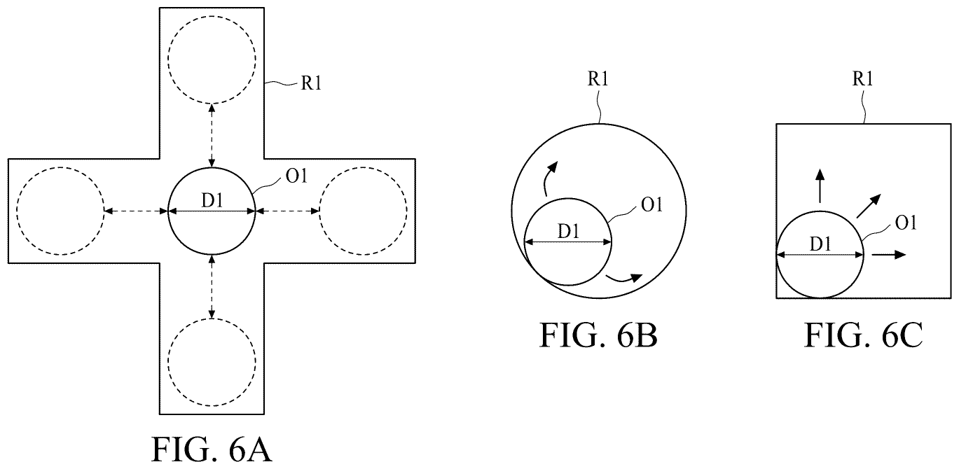

FIGS. 6A to 6C are schematic views of the slots R1 and their corresponding openings O1, according to different embodiments of the present disclosure. In some embodiments, the opening O1 is movable within the slot R1. For example, the opening O1 can be controlled to move in two dimensions within a region of the slot R1. In some embodiments, the slot R1 has a circular, oval, triangular, square, rectangular, rhombic or cross shape. FIG. 6A shows the slot R1 with a cross shape. The opening O1 can move forward, backward, left or right in the cross region. A diameter D1 of the opening O1 is also adjustable. In some embodiments, a maximum value of the diameter D1 less than 1 millimeter (mm). FIG. 6B shows the slot R1 with a circular shape. The opening O1 can slide clockwise or counterclockwise in a circular region. FIG. 6C shows the slot R1 with a square shape. The opening O1 can move left, right or diagonally in the square region.

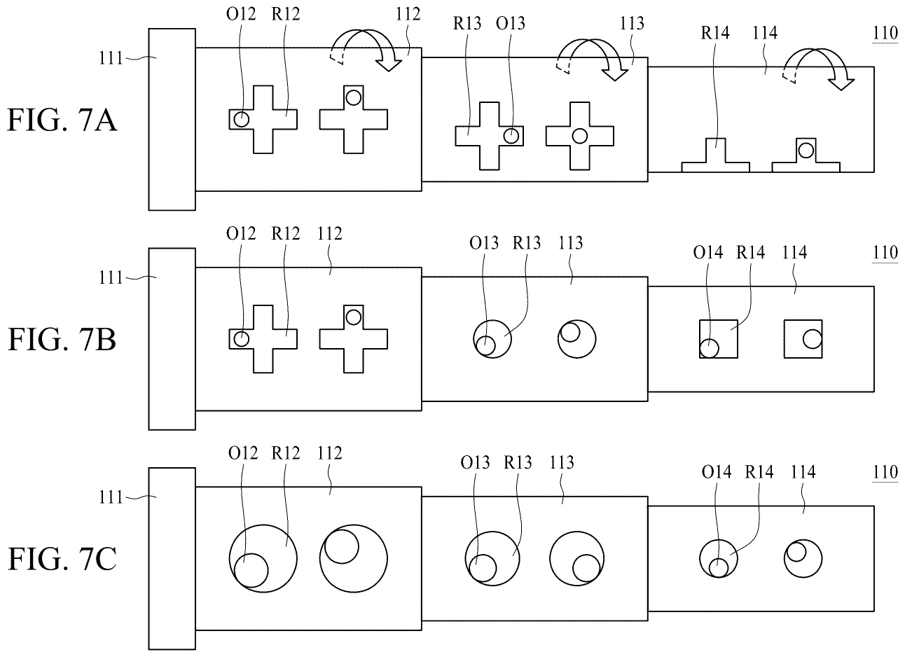

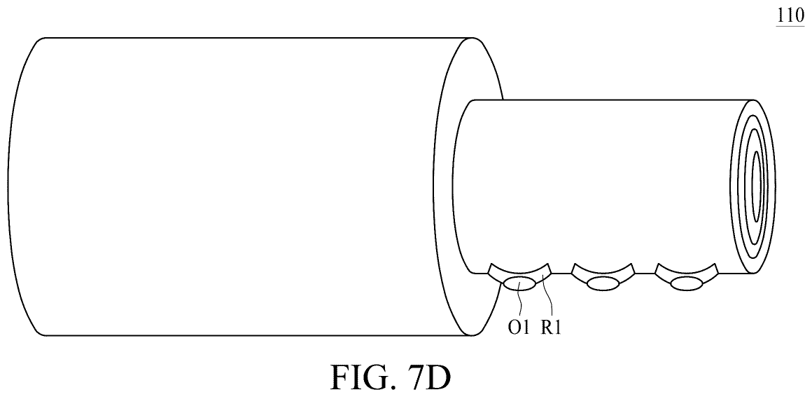

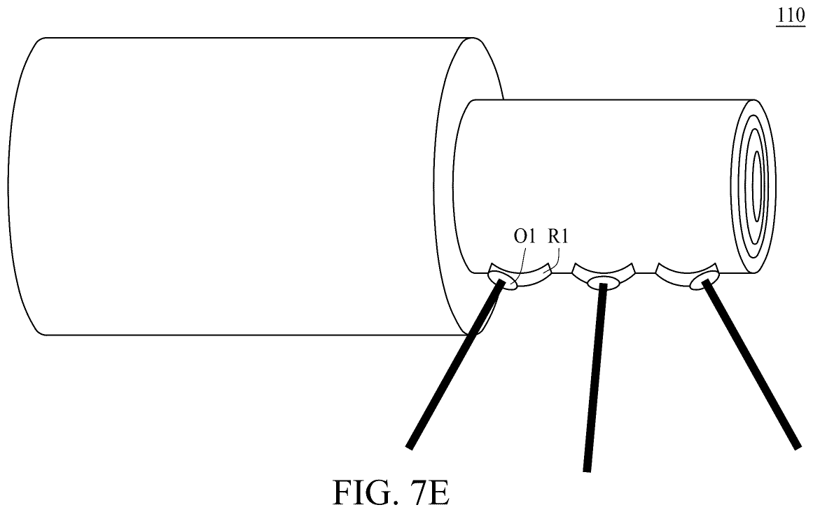

FIGS. 7A to 7E are schematic views of various spraying members 110, according to different embodiments of the present disclosure. For ease of discussion, the slots R1 and the openings O1 on the segment 112 are respectively referred to as slots R12 and openings O12, the slots R1 and the openings O1 on the segment 113 are respectively referred to as slots R13 and openings O13, and the slots R1 and the openings O1 on the segment 114 are respectively referred to as slots R14 and openings O14. The segment 111 may or may not include the opening O1.

Referring to FIG. 7A, in some embodiments, each of the segments 112, 113 and 114 is rotatable, as shown by the arrows. The slots R12, R13 and R14 can be aligned or offset by rotating one or more of the segments 112, 113 and 114. Furthermore, the openings O12, O13 and O14 can be aligned or offset by rotating one or more of the segments 112, 113 and 114 and adjusting positions of the openings O12, O13 and O14 in their corresponding slots R12, R13 and R14, respectively.

Referring to FIG. 7B, in some embodiments, the slots R1 at different segments have different shapes. For example, the slots R12 may have a cross shape, the slots R13 may have a circular shape and the slots R14 may have a square shape, but the present disclosure is not limited thereto. In some embodiments, two of the slots R12, R13 and R14 have a same shape, and the remaining slot has another shape.

Referring to FIG. 7C, in some embodiments, the slots R1 at different segments have different diameters or widths. For example, a diameter of the slot R12 may be greater than a diameter of the slot R13, and the diameter of the slot R13 may be greater than a diameter of the slot R14, but the present disclosure is not limited thereto. In some embodiments, two of the slots R12, R13 and R14 have a same diameter, and the remaining slot has a different diameter. In some embodiments, the openings O1 at different segments have different diameters. For example, a diameter of the opening O12 may be greater than a diameter of the opening O13, and the diameter of the opening O13 may be greater than a diameter of the opening O14, but the present disclosure is not limited thereto. In some embodiments, two of the openings O12, O13 and O14 have a same diameter, and the remaining opening has a different diameter. In some embodiments, diameters of the openings O12, O13 and O14 are respectively adjustable according to practical usages. In some embodiments, diameters of the openings O12, O13 and O14 are less than 1 mm.

Referring to FIGS. 7D and 7E, in some embodiments, the slot R1 is spherical or concave-shaped. In such embodiments, the opening O1 is movable along an axial direction within the slot R1. As such, a fluid discharged out of the opening O1 can have adjustable and different spray directions.

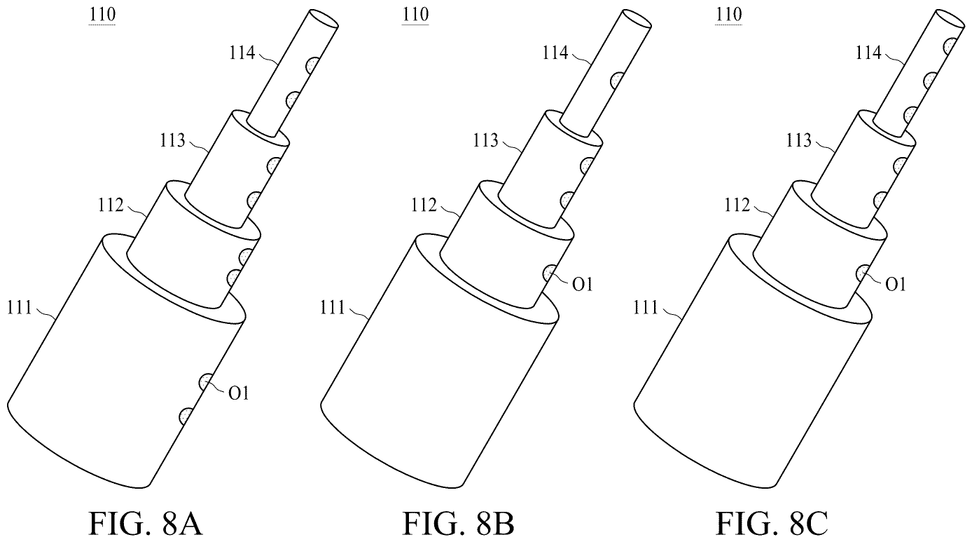

FIGS. 8A to 8C are schematic perspective views of various spraying members 110, according to different embodiments of the present disclosure. In some embodiments, each of the segments has a same number of openings. For example, the number of the openings O1 in each segment can be 1, 2, 3 or more. In FIG. 8A, the number of openings O1 in each of the segments 111, 112, 113 and 114 is 2 (two). In some embodiments, each of the segments has a different number of openings O1. For example, the segment 113 has two openings O1, and each of the segments 111 and 112 has one opening O1, as shown in FIG. 8B. In another example, the segment 111 has no opening O1, the segment 112 has one opening O1, the segment 113 has two openings O1 and the segment 114 has three openings O1, as shown in FIG. 8C.

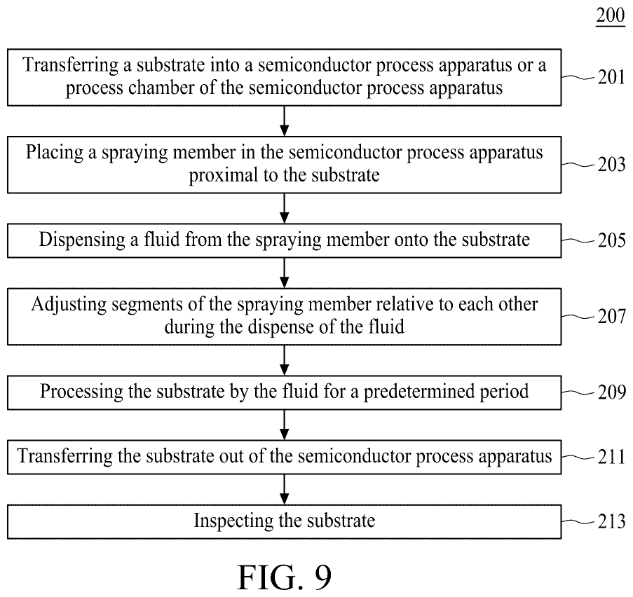

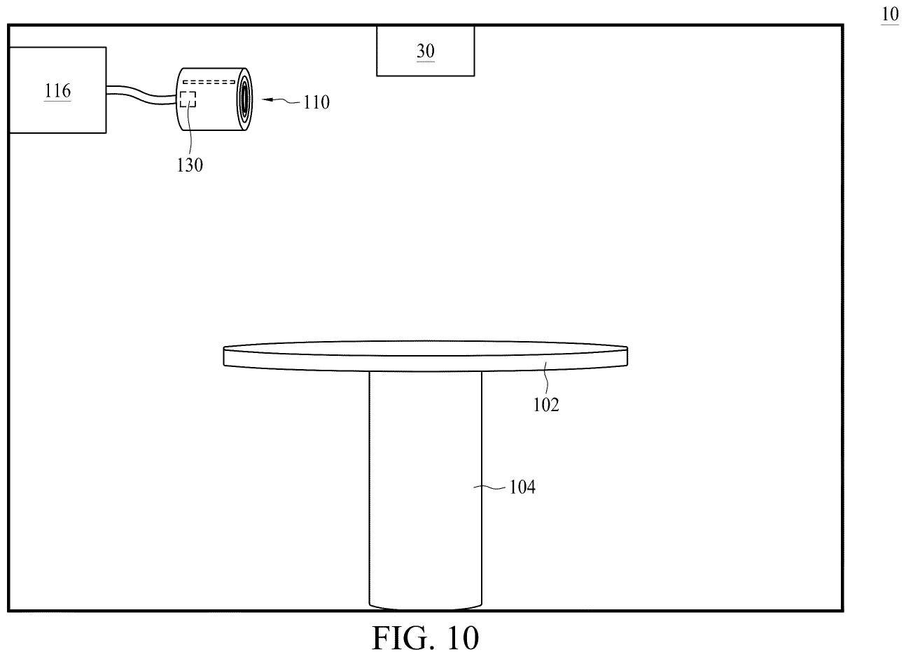

FIG. 9 is a flowchart of a method 200 for processing a substrate, according to some embodiments of the present disclosure. FIGS. 10 to 12 and 13A to 13C are schematic views showing some operations of the method 200 in FIG. 9, according to some embodiments of the present disclosure. Additional operations can be provided before, during, and after each operation of the method 200. Some operations of the method 200 can be replaced, eliminated, repeated or relocated for other embodiments. The method 200 is an example, and is not intended to limit the present disclosure beyond what is explicitly recited in the claims. In some embodiments, the method 200 is used to dispense a chemical liquid onto the substrate 20 using the spraying member 110 in FIG. 1.

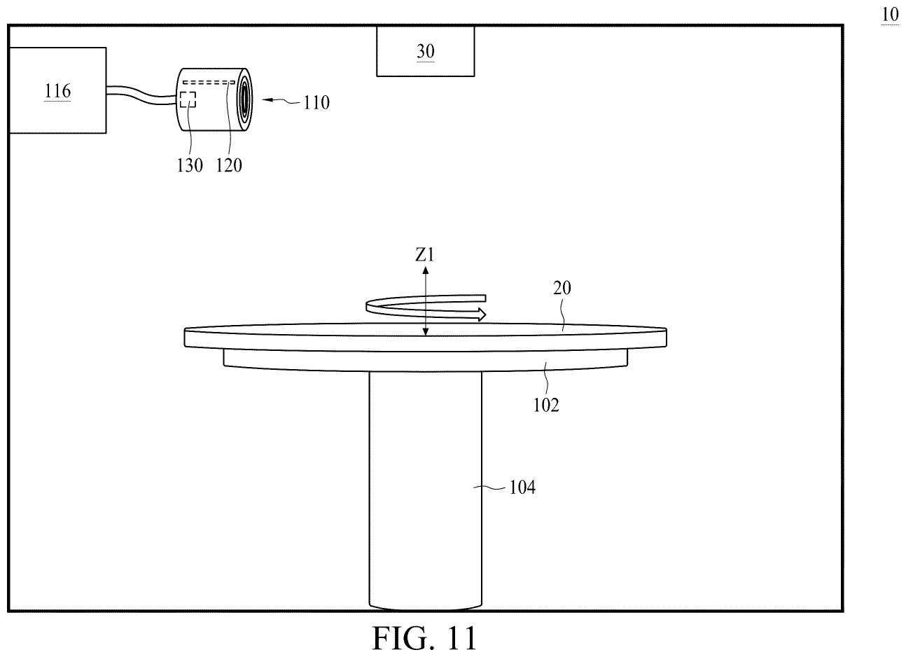

In operation 201 of the method 200 in FIG. 9, a substrate 20 is transferred into a semiconductor process apparatus 10 or a process chamber of the semiconductor process apparatus 10, as shown in FIGS. 10 and 11.

Referring to FIG. 10, in some embodiments, the semiconductor process apparatus 10 is a lithographic apparatus such as a coating tool or a developing tool. In other embodiments, the semiconductor process apparatus 10 is a rinsing apparatus for removing undesired chemicals or particles on the substrate 20. The semiconductor process apparatus 10 includes a platform 102 for supporting the substrate 20. The platform 102 may be positioned in a cup (not shown) for preventing liquids from spraying onto other components in the semiconductor process apparatus 10. The cup includes one or more exhausts to which excess liquid flows.

Referring to FIG. 11, the substrate 20 is placed on the platform 102. In some embodiments, the substrate 20 includes at least one of a photomask, a reticle, a wafer, a wafer coated by a photoresist, a silicon substrate, a glass substrate and a ceramic substrate. The platform 102 may be or include a vacuum chuck for holding the substrate 20 securely. The platform 102 may have a diameter less than a diameter of the substrate 20. In some embodiments, the platform 102 is circular-shaped and rotatable. A rotating motion of the platform 102 is achieved by a shaft 104 connected to and disposed below the platform 102. The shaft 104 can be powered by a motor to rotate at different speeds. As such, the substrate 20 can be rotated along an axis Z1 parallel to a thickness direction of the substrate 20. In other embodiments, the platform 102 is not rotatable.

The semiconductor process apparatus 10 includes one or more spraying members 110 for dispensing chemical liquids onto the substrate 20. The spraying member 110 includes a nozzle or an injector. The spraying member 110 may be disposed above or at a side of the substrate 20, but the present disclosure is not limited thereto. The spraying member 110 is coupled to a fluid source 116 that supplies a chemical liquid to the spraying member 110. In some embodiments, the semiconductor process apparatus 10 includes a sensor 30 for monitoring a spraying process of the spraying member 110.

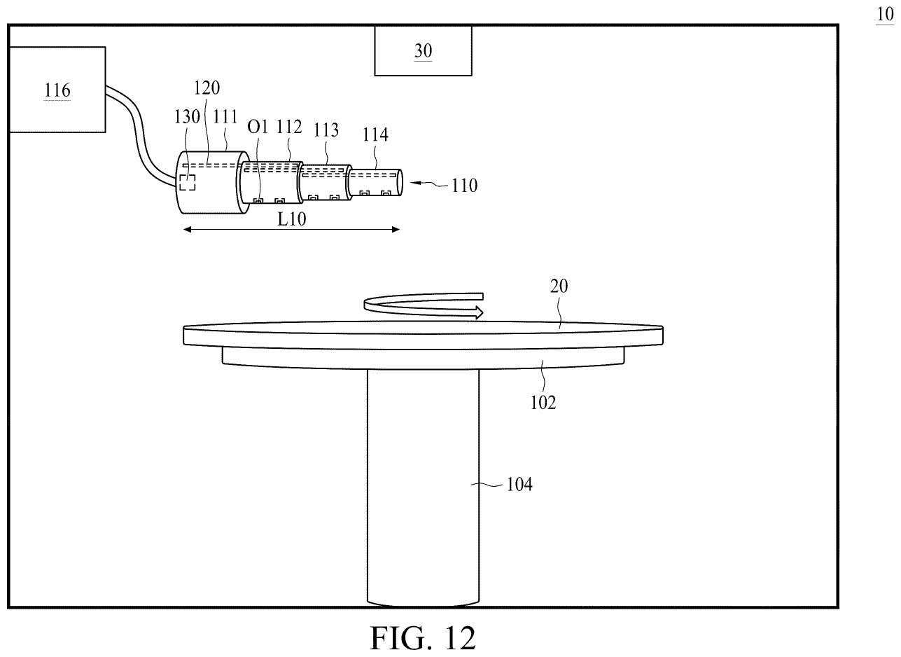

In operation 203 of the method 200 in FIG. 9, the spraying member 110 in the semiconductor process apparatus 10 is placed proximal to the substrate 20, as shown in FIG. 12. In some embodiments, the spraying member 110 is telescopic. The spraying member 110 includes multiple segments, for example, segments 111, 112, 113 and 114 which are connected section by section. The spraying member 110 includes multiple rails 120 respectively coupling adjacent segments. The segments 111, 112, 113 and 114 have different diameters. For example, the segment 111 has a greatest diameter, the segment 112 has a second greatest diameter, the segment 113 has a third greatest diameter, and the segment 114 has a least diameter. The segments 112, 113 and 114 can be stored in the segment 111.

The segments 111, 112, 113 and 114 are adjustable relative to each other. The segment 112 can be extended from the segment 111, the segment 113 can be extended from the segment 112, and the segment 114 can be extended from the segment 113. The spraying member 110 as a whole can become longer by sequentially extending its segments 112, 113 and 114 from the segment 111. A length L10 of the spraying member 110 can be adjusted for substrates having different sizes. Furthermore, the segment 114 can be retracted toward and into the segment 113, the segment 113 can be retracted toward and into the segment 112, and the segment 112 can be retracted toward and into the segment 111. In some embodiments, the spraying member 110 includes a motor 130 installed internal or external to the segments 111, 112, 113 and 114. The motor 130 can receive signals for controlling extension or contraction of the spraying member 110, or rotation of the segments 112, 113 and 114.

The spraying member 110 is moved from its original position to approach the substrate 20. For example, the spraying member 110 can be positioned above a peripheral region or a center region of the substrate 20 (i.e., a work position). A distance between the spraying member 110 and the substrate 20 can also be adjusted. The distance may affect a momentum of a liquid droplet arriving at a contact surface of the substrate 20. The spraying member 110 can have a translational movement trajectory, a rotational movement trajectory, or a combination thereof inside the semiconductor process apparatus 10. In some embodiments, the spraying member 110 is not extended until it finishes movement over the substrate 20. In other embodiments, the spraying member 110 is extended before it is moved to the working position. In other embodiments, the movement of the spraying member 110 and the extension of the segments 112, 113 and 114 are simultaneous.

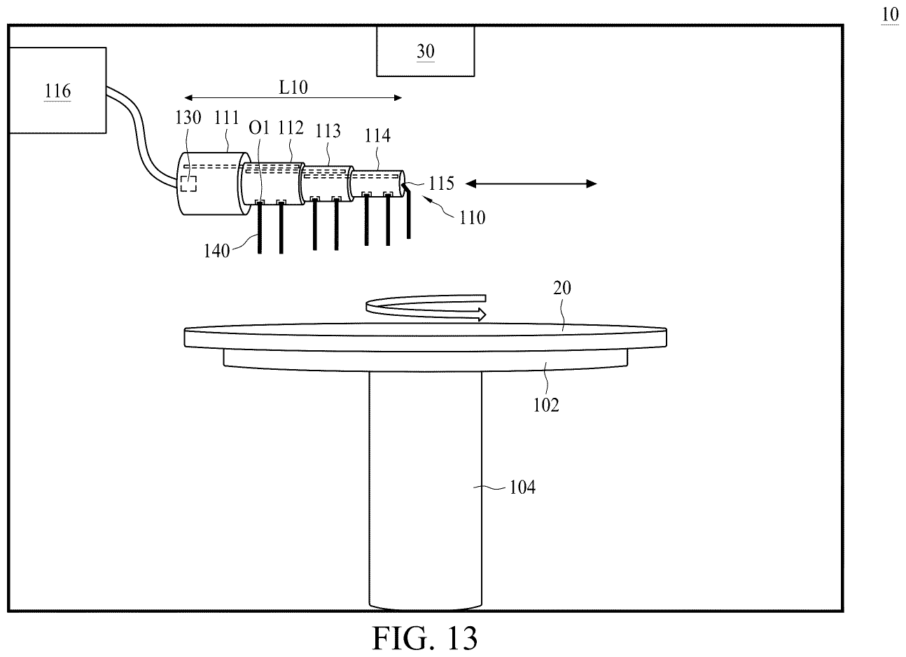

In operation 205 of the method 200 in FIG. 9, a fluid 140 is dispensed from the spraying member 110 onto the substrate 20, as shown in FIG. 13. In some embodiments, the fluid 140 includes deionized (DI) water, standard clean 1 (SC1,which is a mixture of DI water, NH₄OH and H₂O₂), standard clean 2 (SC2, which is a mixture of DI water, HCl and H₂O₂), ozonated de-ionized water (DIW-O₃), SPM (a mixture of H₂SO₄ and H₂O₂), SOM (a mixture of H₂SO₄ and O₃), SPOM, H₃PO₄, dilute hydrofluoric acid (DHF), HF, HF/EG, HF/HNO₃, NH₄OH, and/or other chemicals used in semiconductor processes. In some embodiments, when the semiconductor process apparatus 10 is a lithographic apparatus, the fluid 140 includes a developer such as tetramethylammonium hydroxide (TMAH, N(CH₃)₄OH).

In operation 207 of the method 200 in FIG. 9, the segments 111, 112, 113 and 114 of the spraying member 110 are adjusted relative to each other before or during the dispensing of the fluid 140, as shown in FIGS. 13, 14A to 14C and 15. The fluid 140 is discharged out of the openings O1 of the segments 112, 113 and 114 of the spraying member 110. In some embodiments, when an opening O1 at the end 115 of the segment 114 is opened, the fluid 140 is also dischargeable from the opening O1 at the end 115 of the segment 114. In some embodiments, the discharge of the fluid 140 takes place simultaneously with the extension or the retraction of the spraying member 110, as denoted by the double arrow in FIG. 13. That is, when the fluid 140 is dispensed onto the substrate 20, the length L10 of the spraying member 110 can be dynamically changed. In some embodiments, the substrate 20 is rotated during the discharge of the fluid 140. Therefore, the fluid 140 can be sprayed evenly on the substrate 20.

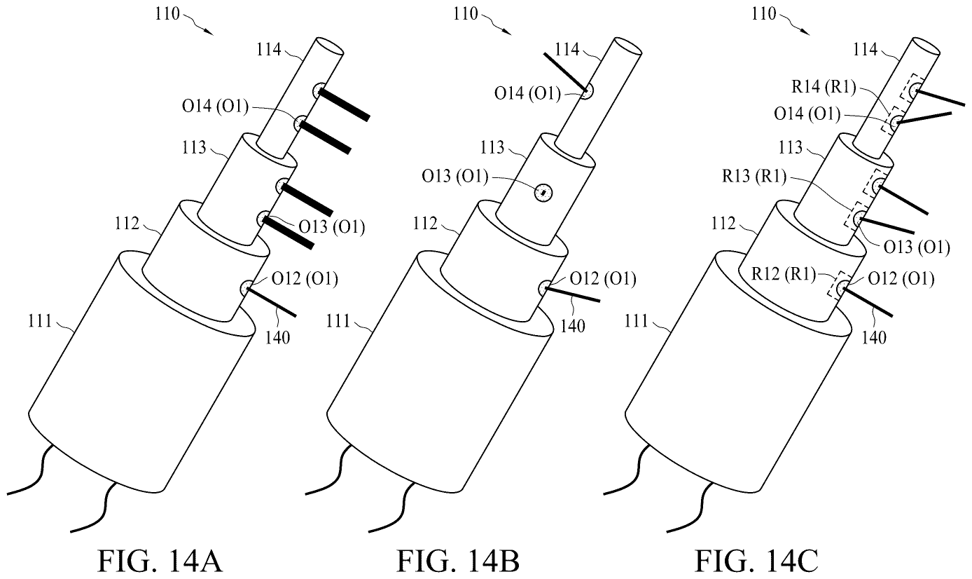

FIGS. 14A to 14C are schematic perspective views showing different dispensing patterns of the fluid 40. In FIGS. 14A and 14B, the slots R1 are not shown. Referring to FIGS. 14A and 6A to 6C, diameters D1 of different openings O1 can be independently adjusted to be larger or smaller. For example, sizes of the openings O12, O13 and O14 may be adjusted to be same or different. In some embodiments, the fluid 140 has different pressures or flow rates as it is discharged from different openings O12, O13 and O14 according to adjustment of the sizes of the openings O12, O13 and O14. In some embodiments, the fluid 140 is pushed by different discharging forces as it is discharged from different openings O12, O13 and O14. The discharging force at each of the openings O12, O13 and O14 can be individually or collectively adjusted to be greater or less. In some embodiments, the fluid 140 can be ejected from the opening O12 at a first flow rate and ejected from the opening O13 at a second flow rate. The first flow rate may be the same as or different from the second flow rate. In some embodiments, when the openings O1 at different segments are aligned with each other, jets of the fluid 140 coming from different openings O1 are substantially parallel to each other.

Referring to FIGS. 14B and 7A, in some embodiments, the discharge of the fluid 140 and rotations of one or more of the segments 112, 113 and 114 of the spraying member 110 take place simultaneously. In some embodiments, the rotation of each of the segments 112, 113 and 114 is independent. Therefore, the fluid 140 can be sprayed in different directions from different openings O1.

Referring to FIGS. 14C and 7A to 7C, in some embodiments, the discharge of the fluid 140 and the movement of the opening O1 within the slot R1 take place simultaneously. That is, during the discharge of the fluid 140, the opening O12 is movable within the slot R12, the opening O13 is movable within the slot R13, and the opening O14 is movable within the slot R14. Therefore, the fluid 140 can be sprayed in different directions from different openings O1.

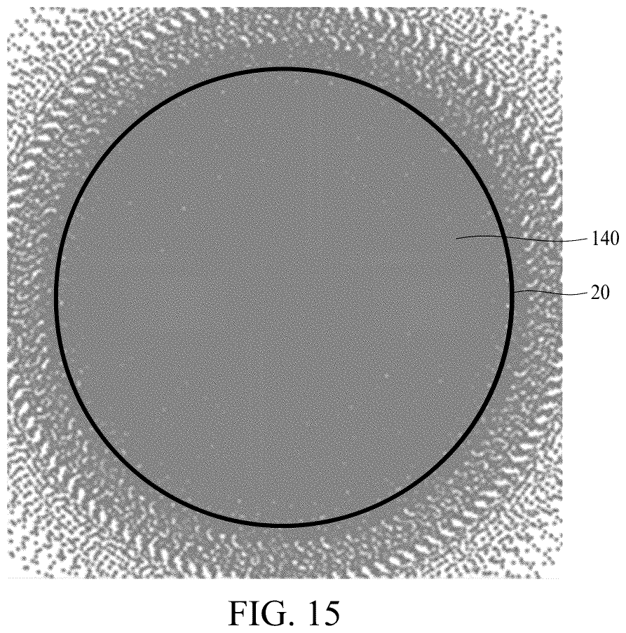

Still referring to FIG. 13, in some embodiments, the sensor 30 is used to monitor a dispensing process of the fluid 140 onto the substrate 20. The sensor 30 may be connected to a recording unit for recording a spraying or dispensing pattern of the fluid 140. FIG. 15 shows a spraying pattern of the fluid 40 on the substrate 20 at a certain instant.

In operation 209 of the method 200 in FIG. 9, the substrate 20 is processed by the fluid 140 for a predetermined period. The substrate 20 may be cleaned by the fluid 140 or some portions of the substrate 20 may react with the fluid 140. For example, when the substrate 20 includes particles and the fluid 140 is a cleaning reagent, the substrate 20 is processed until the particles are sufficiently removed. In another example, when substrate 20 includes an exposed photoresist and the fluid 140 is a developer, the substrate 20 is processed until the exposed photoresist is sufficiently developed. The dispensing of the fluid 140 is stopped after the predetermined period.

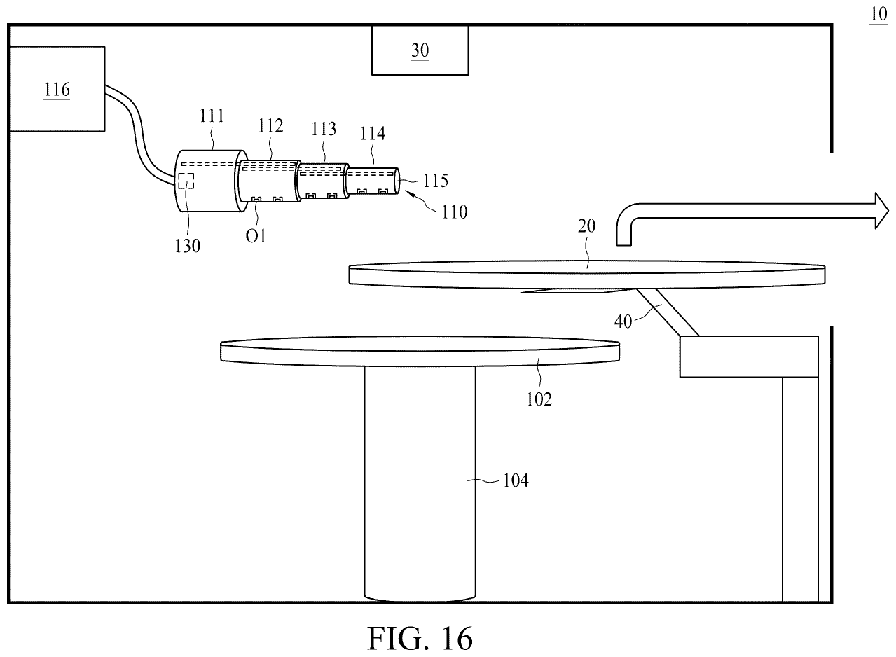

In operation 211 of the method 200 in FIG. 9, the substrate 20 is transferred out of the semiconductor process apparatus 10, as shown in FIG. 16. The substrate 20 may be moved away from the platform 102 and transferred to a FOUP or another semiconductor process apparatus by a robot arm 40.

In operation 213 of the method 200 in FIG. 9, the substrate 20 is inspected. In some embodiments, in order to examine whether a parameter of the processed substrate 20 meets a specific criteria, an inspection is conducted on the substrate 20. For example, when the substrate 20 requires cleaning and the fluid 140 is a cleaning reagent, an optical or electronic examination is conducted to check whether a number of particles on the substrate 20 is low enough. That is, a cleaning performance of the semiconductor process apparatus 10 is examined. In another example, when the substrate 20 includes an exposed photoresist and the fluid 140 is a developer, an after-development inspection (ADI) is conducted to check whether the exposed photoresist is sufficiently removed. That is, a developing performance of the semiconductor process apparatus 10 is examined. When the parameter does not meet the specific criteria, a configuration of the spraying member 110 will be adjusted before another substrate is transferred into the semiconductor process apparatus 10.

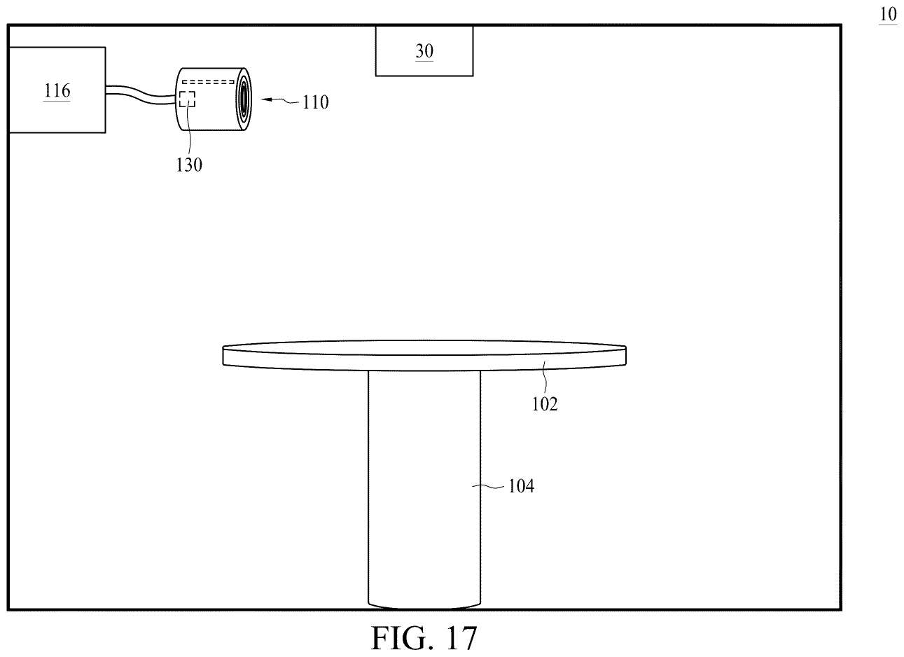

FIGS. 17 to 19 show some operations after the substrate 20 is transferred out of the semiconductor process apparatus 10. These operations may be executed before, during or after operation 213 is performed. Referring to FIG. 17, the spraying member 110 returns back to its initial position in initial configuration.

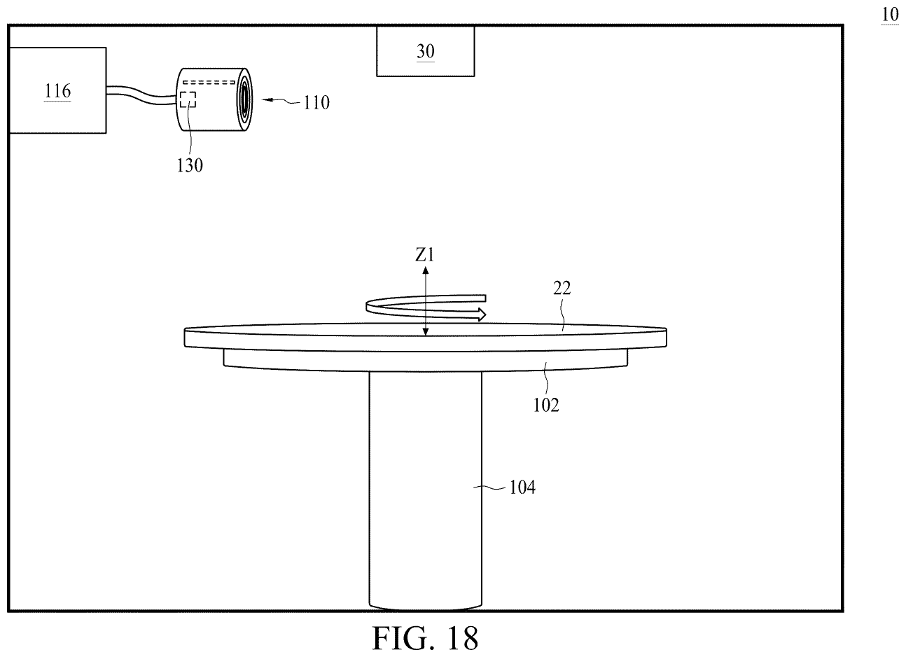

Referring to FIG. 18, after transferring the substrate 20 out of the semiconductor process apparatus 10, another substrate 22 is transferred into the semiconductor process apparatus 10. The substrate 22 is similar to the substrate 20.

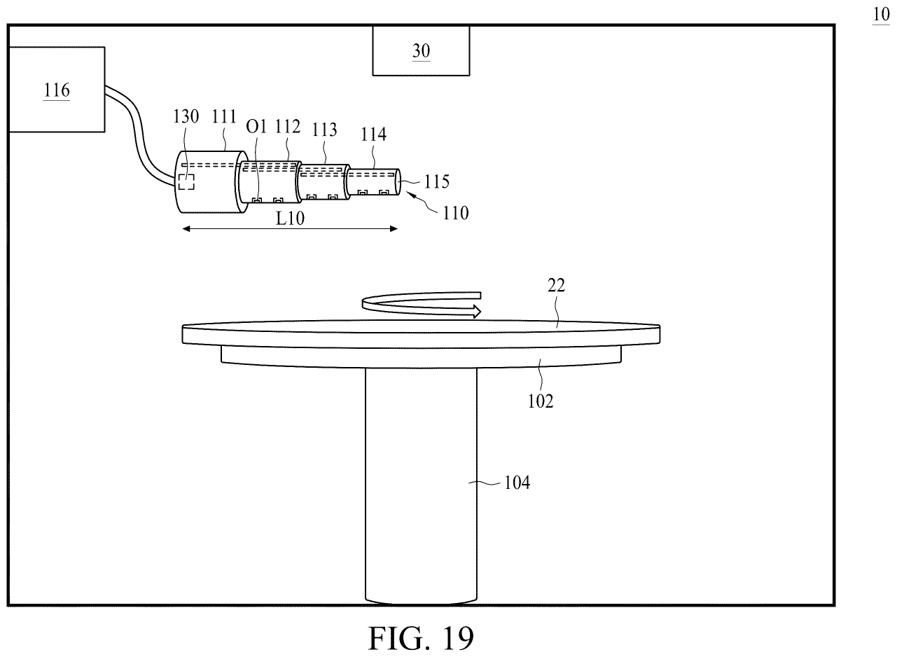

Referring to FIG. 19, the spraying member 110 is placed proximal to the substrate 22. In some embodiments, before the fluid 140 is dispensed from the spraying member 110 onto the substrate 22, the configuration and/or parameters of the spraying member 110 is further adjusted. In some embodiments, the spraying member 110 is configured different from that for processing the previous substrate 20. For example, segments of the spraying member 110 may be further extended, contracted or rotated to have a different configuration, flow rates of the fluid 140 discharged from different openings may be adjusted, the spraying member 110 may be moved or rotated to change its relative position to the substrate 20, or the like. In another example, pressures or flow rates of the fluid 140 discharged from different openings are respectively tuned by adjusting sizes of the openings.

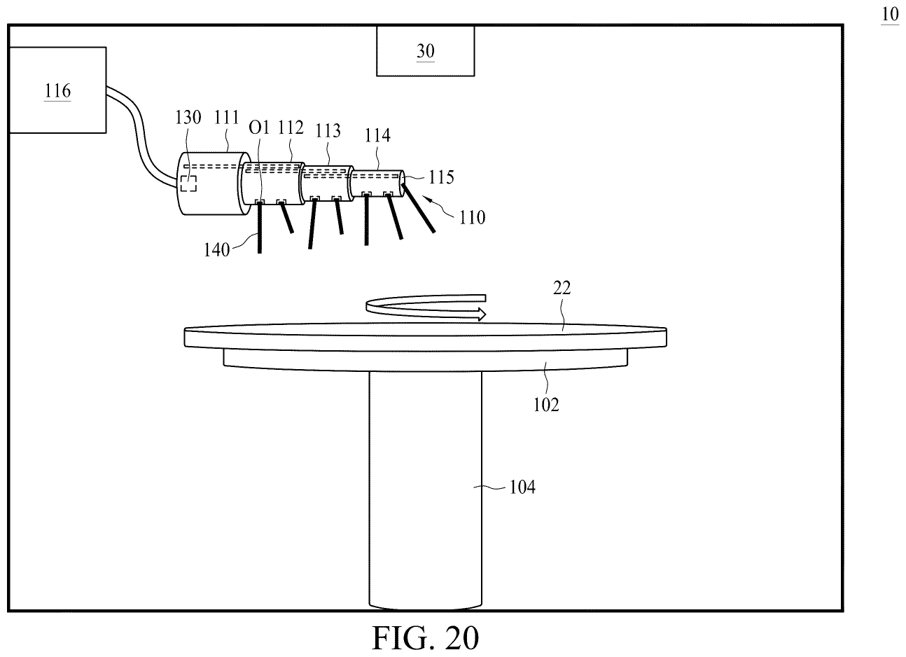

In some embodiments, after adjusting the configuration of the spraying member 110, the fluid 140 is discharged out of the spraying member 110, as shown in FIG. 20. In some embodiments, the spraying pattern of the fluid 140 for processing the substrate 22 is different from the spraying pattern of the fluid 140 for processing the substrate 20. In some embodiments, the configuration of the spraying member 110 is adjusted continuously during the discharging of the fluid 140.

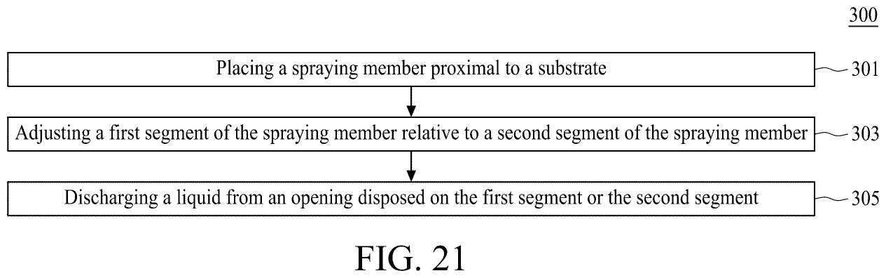

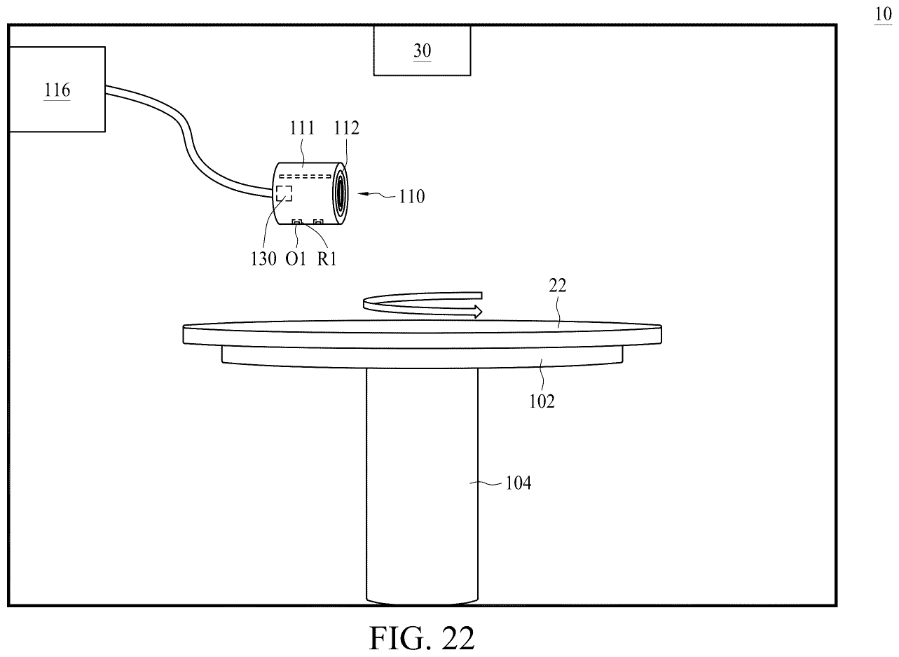

FIG. 21 is a flowchart of a method 300 for processing a substrate, according to some embodiments of the present disclosure. FIGS. 22 to 25 are schematic views showing some operations of the method 300 in FIG. 21, according to some embodiments of the present disclosure. Additional operations can be provided before, during, and after each operation of the method 300. Some operations of the method 300 can be replaced, eliminated, repeated or relocated for other embodiments. The method 300 is an example, and is not intended to limit the present disclosure beyond what is explicitly recited in the claims. In some embodiments, the method 300 is used to dispense a chemical liquid onto the substrate 20 using the spraying member 110 in FIG. 1.

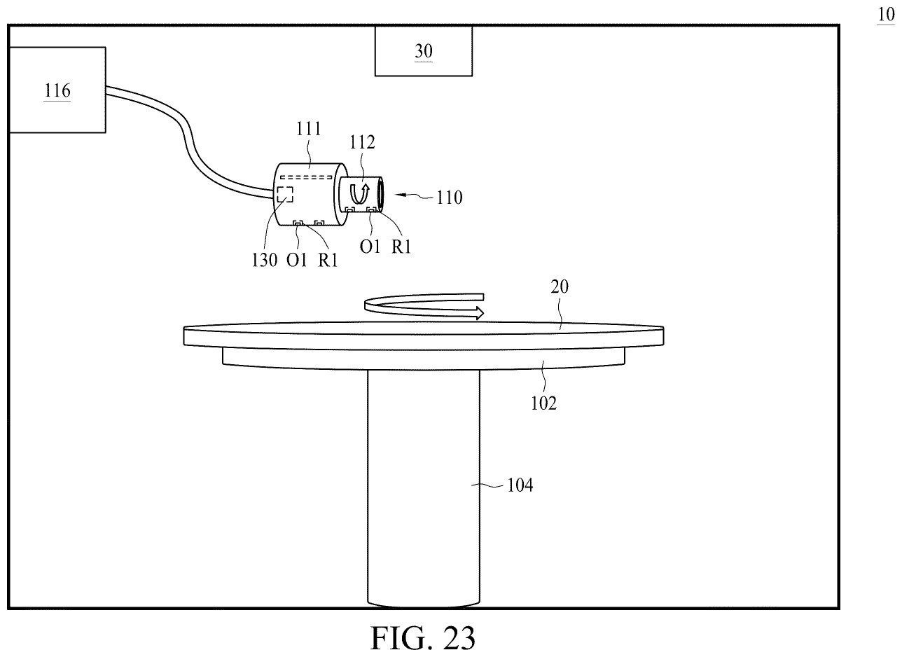

In operation 301 of the method 300 in FIG. 21, a spraying member 110 is placed proximal to a substrate 20, as shown in FIG. 22. The spraying member 110 is moved from its original position to approach the substrate 20. For example, the spraying member 110 can be positioned above a peripheral region or a center region of the substrate 20. The spraying member 110 can have a translational movement trajectory, a rotational movement trajectory, or a combination thereof inside the semiconductor process apparatus 10. A distance between the spraying member 110 and the substrate 20 can also be adjusted. The distance may affect a momentum of a liquid droplet arriving at a contact surface of the substrate 20. The spraying member 110 at least includes a segment 111 and a segment 112 coupled to the segment 111. The segment 112 may be extended from and stored in the segment 111. In some embodiments, the segment 111 includes one or more slots R1. In other embodiments, the segment 111 does not include any slot. In some embodiments, the segment 112 includes one or more slots R1 (will be shown in FIG. 23). Each slot R1 includes an opening O1 for discharging liquids.

In operation 303 of the method 300 in FIG. 21, the segment 112 is adjusted relative to the segment 111, as shown in FIG. 23. The spraying member 110 as a whole can become longer by extending the segment 112 out of the segment 111. The segment 112 can be rotated in a clockwise or counterclockwise direction with respect to the segment 111. Furthermore, a position of the opening O1 in the slot R1 can be adjusted, as shown in FIGS. 6A to 6C.

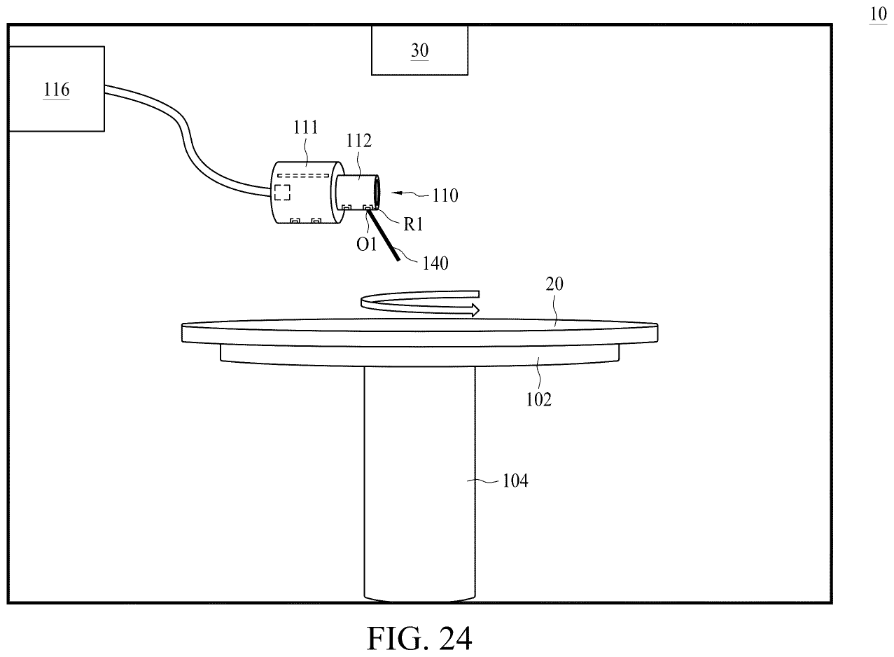

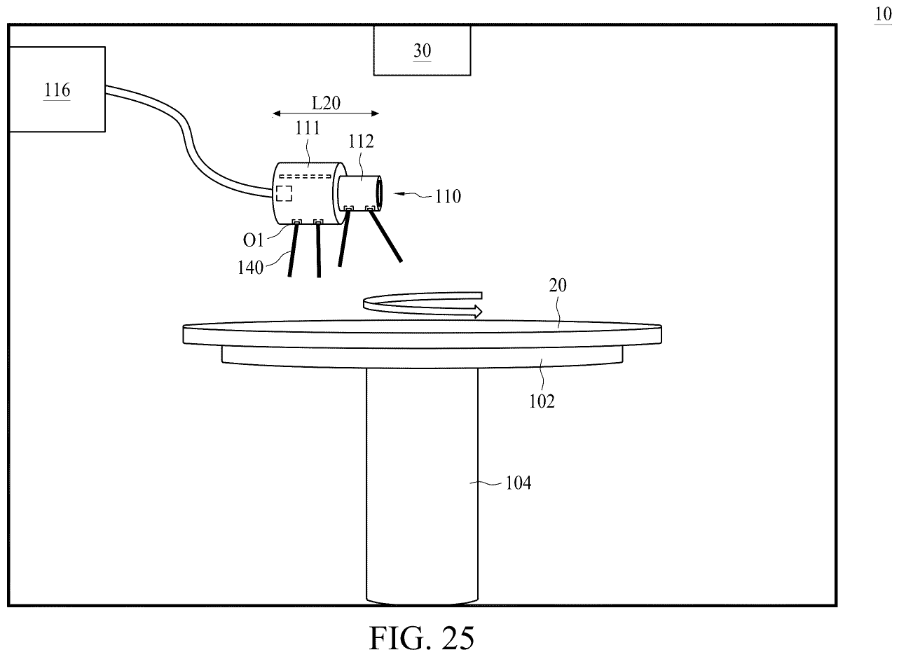

In operation 305 of the method 300 in FIG. 21, a fluid 140 is discharged from an opening O1 disposed on the segment 111 or the second segment, as shown in FIGS. 24 and 25. Referring to FIG. 24, in some embodiments, the fluid 140 is discharged from one of the openings O1. By adjusting a position of the opening O1 within its corresponding slot R1, a jet or spraying direction of the fluid 140 coming from such opening O1 can be changed.

Referring to FIG. 25, in some embodiments, the fluid 140 is discharged from multiple openings O1 of the spraying member 110. Jets or spraying directions of the fluid 140 coming from different openings O1 can be individually or collectively adjusted.

Various chemicals are widely used in semiconductor processes. For example, photoresists and surface modifiers are used in lithographic processes, and cleaning reagents such as SC1 and SC2 are used in cleaning processes. These reagents are sprayed onto a semiconductor substrate such as a wafer or a substrate via a spraying member.

The present disclosure provides a telescopic spraying member and a method for using the telescopic spraying member to discharge one or more chemicals onto a substrate. The telescopic spraying member is connected to a liquid source which contains a liquid or fluid reagent supplied to the telescopic spraying member for dispensing. The telescopic spraying member includes multiple segments such as 4 or more segments connected by rails. These segments can be extended or contracted to adjust their exposed length in order to adjust a total length of the telescopic spraying member. Besides, these segments can be rotated for adjusting orientations of openings on the segments. Furthermore, each of the segments includes one or more slots, and the openings are respectively disposed in the slots. The slots have various shapes, and the opening can be moved within the slot. During the spraying process, as the opening moves in the slot, directions of the ejected liquid can be dynamically changed. Therefore, the telescopic spraying member can spray a chemical fluid evenly on a semiconductor substrate, or can spray chemical fluid at different angles toward the semiconductor substrate. Furthermore, the telescopic spraying member can be applied to different substrates having different sizes.

One aspect of the present disclosure provides a method of processing a substrate. The method includes: placing a spraying member proximal to the substrate, wherein the spraying member includes a first segment and a second segment coupled to the first segment, the first segment is adjustable relative to the second segment, and the first segment has a first opening configured to discharge a fluid out of the spraying member; adjusting the first segment relative to the second segment; and discharging the liquid from the first opening.

One aspect of the present disclosure provides another method of processing a substrate. The method includes: transferring the substrate into a process chamber; adjusting a spraying member disposed adjacent to the substrate, wherein the spraying member includes a plurality of segments adjustable relative to each other; discharging a fluid from the spraying member toward the substrate; and transferring the substrate out of the process chamber. The adjustment of the spraying member includes adjusting at least one of the plurality of segments relative to another one of the plurality of segments.

Another aspect of the present disclosure provides a spraying member for processing a substrate. The spraying member includes a first segment and a second segment coupled to the first segment. The first segment has a first opening configured to discharge a fluid out of the spraying member. The first segment is extendable from, retractable toward or rotatable relative to the second segment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of processing a substrate, comprising:
placing a spraying member proximal to the substrate, wherein the spraying member includes a first segment and a second segment coupled to the first segment, the first segment is adjustable relative to the second segment, and the first segment has a first opening configured to discharge a fluid out of the spraying member;
adjusting the first segment relative to the second segment; and
discharging the liquid from the first opening.

2. The method of claim 1, wherein the adjustment of the first segment includes extending the first segment from the second segment, retracting the first segment toward the second segment, or rotating the first segment relative to the second segment.

3. The method of claim 2, wherein the first segment is adjusted relative to the second segment along a rail on the first segment or the second segment.

4. The method of claim 1, further comprising moving the first opening relative to and along a slot of the first segment, or adjusting a first size of the first opening.

5. The method of claim 1, wherein the second segment is adjustable relative to the first segment, and the second segment has a second opening configured to discharge the fluid out of the spraying member.

6. The method of claim 5, wherein the adjustment of the first segment includes aligning the first opening with the second opening or offsetting the first opening from the second opening.

7. The method of claim 5, further comprising adjusting a first size of the first opening and adjusting a second size of the second opening, wherein the first size is substantially different from or substantially same as the second size.

8. The method of claim 5, wherein the discharging of the liquid includes discharging the liquid from the first opening at a first flow rate, and discharging the liquid from the second opening at a second flow rate substantially different from or substantially same as the first flow rate.

9. A method of processing a substrate, comprising:
transferring the substrate into a process chamber;
adjusting a spraying member disposed adjacent to the substrate, wherein the spraying member includes a plurality of segments adjustable relative to each other;
discharging a fluid from the spraying member toward the substrate; and
transferring the substrate out of the process chamber,
wherein the adjustment of the spraying member includes adjusting at least one of the plurality of segments relative to another one of the plurality of segments.

10. The method of claim 9, wherein the adjustment of the spraying member and the discharging of the fluid are conducted simultaneously.

11. The method of claim 9, wherein the adjustment of the spraying member includes extending, retracting or rotating at least one of the plurality of segments relative to another one of the plurality of segments.

12. The method of claim 9, wherein each of the plurality of segments has at least one adjustable opening, and the adjustment of the spraying member includes adjusting at least one of the adjustable openings relative to a corresponding one of the plurality of segments prior to the discharging of the fluid from the spraying member.

13. The method of claim 9, wherein the substrate is rotated during the discharging of the fluid.

14. The method of claim 9, wherein the spraying member is disposed above the substrate or at a side of the substrate during the discharging of the fluid.

15. The method of claim 9, wherein the substrate includes at least one of a photomask, a reticle, a wafer, a silicon substrate, a glass substrate and a ceramic substrate.

16. A spraying member, comprising:
a first segment; and
a second segment coupled to the first segment,
wherein the first segment has a first opening configured to discharge a fluid out of the spraying member, and
the first segment is extendable from, retractable toward or rotatable relative to the second segment.

17. The spraying member of claim 16, wherein the second segment has a second opening configured to discharge a fluid out of the spraying member, and the second segment is extendable from, retractable toward or rotatable relative to the first segment.

18. The spraying member of claim 17, wherein a first size of the first opening is substantially different from or same as a second size of the second opening, and the first size and the second size are substantially less than 1 millimeter (mm) respectively.

19. The spraying member of claim 16, further comprising:
a first slot on the first segment, wherein the spraying member is configured to allow the first opening to move along or within the first slot;
a first rail on at least one of the first segment and the second segment, wherein the first rail is configured to allow the first segment to extend from or retracting toward the second segment.

20. The spraying member of claim 16, wherein the second segment is stationary relative to the first segment.
